(19) United States
(12) Patent Application Publication
(10) Pub. No.: US 2025/0314708 A1
(43) Pub. Date: Oct. 9, 2025

(54) METHOD FOR DETECTING A RISK OF MALFUNCTION THROUGH IMBALANCE OF A DEVICE FOR STORING ENERGY COMPRISING A SET OF LEVELS OF ELECTROCHEMICAL CELLS

(71) Applicant: SOCOMEC, Benfeld (FR)

(72) Inventors: Arnaud DELAILLE, La Ravoire (FR); Bramy PILIPILI MATADI, Chambery (FR); Benoît RICHARD, SAINT-BALDOPH (FR)

(73) Assignee: SOCOMEC, Benfeld (FR)

(21) Appl. No.: 18/868,667

(22) PCT Filed: May 25, 2023
(86) PCT No.: PCT/EP2023/064067

§ 371 Date: Jun. 12, 2025

(30) Foreign Application Priority Data
May 25, 2022 (FR) FR2205038

(51) Int. Cl. G01R 31/392; G01R 31/36; G01R 31/367; G01R 31/3828; G01R 31/3842; G01R 31/396

(52) U.S. Cl. CPC G01R 31/392; G01R 31/3646; G01R 31/367; G01R 31/3828; G01R 31/3842; G01R 31/396

(57) ABSTRACT

The invention relates to a method for detecting a risk of malfunction through imbalance of a device (1) for storing energy comprising a set of levels (2) electrically connected to one another in series and consisting of electrochemical cells electrically connected to one another in parallel, characterised in that it comprises a step (E2) of determining a first function (f1) characterising a correct operation of at least one level, the first step determining a relation between, on the one hand, a magnitude relative to a quantity of charges circulating in at least one level and, on the other hand, a voltage at the terminals of at least one level, the first function being defined according to a voltage range (P).

### TECHNICAL FIELD OF THE INVENTION

The invention relates to the technical field of the monitoring of devices for storing energy comprising a set of levels of electrochemical cells, the levels being electrically connected in series, each level comprising one to several electrochemical cells in parallel, in particular, cells of the lithium-ion type. More specifically, the invention relates to a method for detecting a risk of malfunction through imbalance between the series levels of such a device for storing energy. The invention also relates to monitoring equipment configured to implement such a detection method.

### PRIOR ART

Certain devices for storing energy comprise a set of levels of electrochemical cells, in particular, of the lithium-ion type, electrically connected in series in order to obtain a required target voltage, each level comprising one or more electrochemical cells electrically connected in parallel in order to obtain a required target capacity. For different reasons, an imbalance in the state of charge, commonly referred to as the SOC or State-of-Charge, may appear between the levels in series. This imbalance is commonly referred to as a “cell imbalance”. Possible reasons include problems of dispersion of the state of charge during the assembly of the cells, dispersion problems regarding self-discharge, capacity, or resistance between the cells, which may themselves be the consequence of dispersion problems regarding the manufacture of the cells, or dispersion problems regarding the conditions of use in operation resulting in different ageing kinetics. On observation, these imbalances are most often corrected by an electronic balancing system. However, it is possible that the imbalance is such that it cannot be compensated.

This imbalance may then cause a level to prematurely reach its maximum charging capacity, respectively its maximum discharge, before the other levels in series. If the level continues to be charged after it has reached its maximum charging capacity, respectively its maximum discharge capacity, this may result in an overcharge, respectively an under-discharge. These conditions may induce undesirable heating of the series level concerned, cause thermal runaway, or even the entire device for storing energy catching fire.

To detect a risk of imbalance of an electrochemical level of a device for storing energy, the most common method is based on observing the voltage at the terminals of each level in series during a full charge or discharge of the electrochemical storage system. The level of electrochemical cells with a risk of imbalance, or already imbalanced, generally has a voltage at its terminals that is significantly different from the voltage at the terminals of the other levels and may thus be identified.

However, this method does have some disadvantages. The voltage differences observed are themselves dependent on the conditions of use, namely the temperature, and charge and discharge current. These observed voltage differences are also a result of the states of charge and states of health, commonly referred to as the SOH or State-of-Health, recorded at the time of their observation. Lastly, differences in state of charge do not necessarily result in differences in voltage, in particular, in the case of Lithium Iron Phosphate (LFP) batteries, i.e., batteries based on iron phosphate at the positive electrode, which have a very stable voltage value over a wide operating range, in other words, over a wide range of state of charge. This method thus appears, in practice, to be difficult to calibrate to avoid false alarms, or even insufficient in certain configurations.

On the other hand, the voltage differences between levels are sometimes too small or become sufficiently large only very late in the conditions of use, and that may then lead to a safety problem once detected. Thus, when a risk of imbalance is detected by this means, it is generally necessary to urgently interrupt the use of the device for storing energy; this greatly disrupts the various equipment connected to it. As a result, state-of-the-art detection methods do not provide simple, smooth maintenance management of devices for storing energy.

State of health indicators are also known, which provide an indicator of the state of ageing of a device for storing energy or of a level composing the device for storing energy. Such indicators are complex to calculate and do not make it possible to detect a risk of malfunction through imbalance of at least one level of electrochemical cells composing the device for storing energy.

At the same time, with the widespread use of equipment incorporating energy storage units, notably motor vehicles incorporating lithium-ion batteries, there is an increasing quantity of so-called second-life energy storage units, which may be used for stationary energy storage, notably, to store electrical energy produced by an intermittent energy production source (e.g., solar or wind power) having a view to gradually supplying this energy. These different energy storage units are assembled and electrically connected together in order to form a device for storing energy having a larger capacity. Because the energy storage units which comprise such energy storage devices may have different levels of use, wear or age, the risk of observing an imbalance between the energy storage units is particularly high.

### PRESENTATION OF THE INVENTION

The aim of the invention is to provide a method for detecting a risk of malfunction through imbalance of a device for storing energy comprising a set of levels of electrochemical cells, the levels being electrically connected in series, the detection method overcoming the above-mentioned disadvantages and improving the detection methods known from the prior art.

More precisely, an aim of the invention is to provide a method for detecting a risk of malfunction through imbalance that may be implemented during partial charges and/or discharges of the device for storing energy, and making it possible to detect such a risk at an early stage.

### SUMMARY OF THE INVENTION

The invention relates to a method for detecting a risk of malfunction through imbalance of a device for storing energy comprising a set of levels electrically connected to one another in series and consisting of electrochemical cells electrically connected to one another in parallel, the detection method comprising:
a step of determining a first function characterising a correct operation of at least one level, the first function defining a relationship between, on the one hand, a magnitude relative to a quantity of charges circulating in at least one level and, on the other hand, a voltage at the terminals of at least one level, the first function being defined over a given voltage range,
a step of determining a second function characterising the operation of a level having the lowest voltage at its terminals among all of the levels of the device for storing energy, the second function defining a relationship between, on the one hand, said magnitude relative to a quantity of charges circulating in the level having the lowest voltage at its terminals among all of the levels of the device for storing energy and, on the other hand, a voltage at the terminals of this level, the second function being defined over said voltage range, then
a step of calculating an amplitude value difference or an integral value difference between said first function and said second function, and then
a step of comparing said difference with a threshold.

The first function may define a relationship between, on the one hand, a mean over all of the levels of the device for storing energy of said magnitude relative to a quantity of charges circulating in each level and, on the other hand, a mean voltage at the terminals of each level of the device for storing energy.

Said value relative to a quantity of charges circulating in a level may be an incremental capacitance of this level.

Said voltage range may comprise a lower limit and an upper limit, the lower limit corresponding to a first inflection point of the first function and/or the upper limit corresponding to a second inflection point of the first function, the first inflection point and the second inflection point being positioned on either side of a maximum value reached by the first function.

The first function may reach a maximum value for a given voltage value, and said voltage range may comprise a lower limit and an upper limit, the lower limit being strictly greater than the voltage value for which the first function reaches the maximum value or the upper limit being strictly less than the voltage value for which the first function reaches the maximum value.

The detection method may comprise a step of defining said voltage range comprising:
a sub-step of calculating an offset of the first function compared to a previous iteration of the detection method, and then,
a sub-step of calculating a lower limit and an upper limit of the voltage range according to the previously calculated offset.

Said first function and/or said second function may be determined:
either during a charging or discharging phase of the device for storing energy according to a slow rate, in particular, a rate of less than or equal to C/5,
or during a phase for charging or discharging the device for storing energy according to a fast rate, in particular, a rate strictly greater than C/5, the step (E2, E3) of determining the first function and/or the second function then comprising a sub-step of filtering the magnitude relative to a quantity of charges circulating in a level.

Said difference may be equal to:
the difference between an integral of the first function over said voltage range, and an integral of the second function over said voltage range, or
the difference between a maximum value of the first function over said voltage range and a maximum value of the second function over said voltage range.

Said first function and/or said second function may be determined during a charge or a partial discharge of the device for storing energy, said voltage range comprising a lower limit corresponding to a state of charge of the device for storing energy of greater than or equal to 25% and/or said voltage range comprising an upper limit corresponding to a state of charge of the device for storing energy of less than or equal to 75%.

The step of comparing said difference from a threshold may comprise:
a sub-step of comparing said difference with a first threshold and to a second threshold, the second threshold being strictly greater than the first threshold, and then
a sub-step of recording a first warning signal indicating a moderate risk, if said difference is greater than or equal to the first threshold and strictly less than the second threshold, and
a sub-step of recording a second warning signal indicating a high risk, if said difference is greater than or equal to the second threshold.

The first threshold may be determined as a function of an observed dispersion of said magnitude relative to a quantity of charges circulating in a level, and the second threshold may be determined as a function of an overcharge permissible by the level before thermal runaway.

The invention also relates to equipment for monitoring a device for storing energy comprising a set of electrochemical levels electrically connected in series, the monitoring equipment comprising hardware and software means configured to implement the method for detecting a risk of malfunction through imbalance of the device for storing energy, as defined above.

The invention also relates to a computer program product comprising program code instructions saved on a computer readable medium for implementing the steps of the detection method as defined above when said program is running on a computer.

The invention also relates to a data recording medium, readable by a computer, on which a computer program is saved comprising program code instructions for implementing the detection method as defined above.

### PRESENTATION OF THE FIGURES

These objects, features and advantages of the present invention will be discussed in detail in the following description of a particular non-limiting embodiment i in relation to the accompanying figures, among which:

FIG. 1 is a schematic view of a device for storing energy to which monitoring equipment is connected according to one embodiment of the invention.

FIG. 2 is a block diagram of a method for detecting a risk of malfunction through imbalance of a device for storing energy according to an embodiment of the invention.

FIG. 3 is a graph showing the incremental capacitance of levels in series of the device for storing energy as a function of a voltage at the terminals of each level (or group of levels).

FIG. 4 is a graph showing the voltage at the terminals of the levels of the series (or group of levels) of the device for storing energy as a function of a quantity of electrical charges accumulated by each level (or group of levels).

FIG. 5 is a graph illustrating the temporal evolution of a maximum incremental capacitance value of the level (or group of levels) having the highest voltage at its terminals and of the level (or group of levels) having the lowest voltage at its terminals.

FIG. 6 is a graph illustrating the temporal evolution of an integral value of incremental capacitance of the level (or group of levels) having the highest voltage at its terminals and of the level (or group of levels) having the lowest voltage at its terminals.

FIG. 7 is a graph illustrating the temporal evolution of a difference relative to a mean of the amplitude of a function characterising the level having the lowest voltage at its terminals and of a function characterising the level having the highest voltage at its terminals.

### DETAILED DESCRIPTION

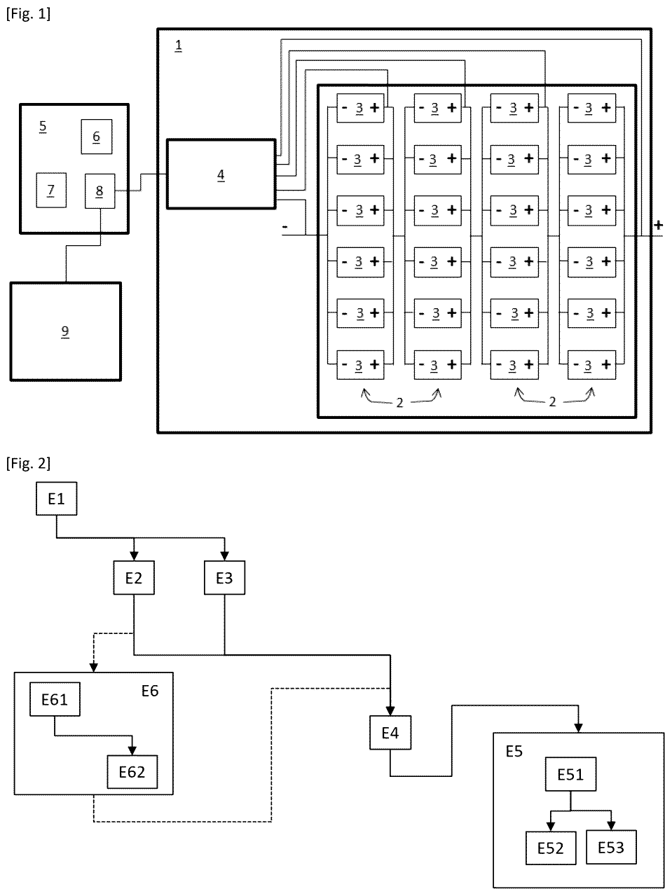

FIG. 1 schematically illustrates a device for storing energy 1 comprising a set of electrochemical cell levels 2 electrically connected to one another. The levels 2 are electrically connected in series. Each level 2 may comprise one or more electrochemical cells 3, also called “accumulators” or “rechargeable batteries”, electrically connected to one another in series and/or in parallel. Each cell 3 comprises one positive electrode, or cathode, and one negative electrode, or anode. The cathodes of the different cells 3 are directly or indirectly connected to a positive terminal of a level 2. Similarly, the anodes of the different cells 3 are connected directly or indirectly to a negative terminal of a level 2. The positive and negative terminals of each level 2 are respectively connected, directly or indirectly, to a positive and negative terminal of the device for storing energy 1. The different levels can be removably assembled in the device for storing energy, so that they can be removed and/or replaced.

According to the embodiment illustrated in FIG. 1, the device for storing energy 1 comprises four levels 2 electrically connected in series. Each level 2 comprises six cells 3, electrically connected in parallel. In a variant, the number of levels 2 and/or cells 3 may be different. Advantageously, all levels 2 comprise an identical number and arrangement of cells 3. Thus, they may comprise substantially identical theoretical modes of operation, in particular, voltages at their terminals and a capacitance, which are comparable.

The levels 2 and/or the cells 3 composing the device for storing energy 1 may optionally be respectively so-called second-life levels and/or cells, i.e., levels and/or cells resulting from a re-manufacturing process after having been integrated into a first system. For example, the device for storing energy 1 may be composed of a set of electric or hybrid automotive vehicle batteries. These batteries may have been used to store energy for the propulsion of the vehicle during its first service life, and then have been disassembled to be reused for a second time, whilst the vehicle was in operation. The device for storing energy 1 may be intended to store electrical energy produced by an intermittent source of energy production (for example, solar or wind energy).

The cells 3 composing the device for storing energy 1 are preferably cells of the lithium-ion type. In such cells, lithium ions may be reversibly exchanged between the positive electrode and the negative electrode. All of the cells 3 of the same device for storing energy 1 preferably have the same chemical composition. The negative electrode may comprise a graphite-based (LixC6) material or a lithium titanate-based (LTO) material. The positive electrode may be based on one of the following materials:
Lithium Iron Phosphate (LFP),
Lithium Nickel Manganese Cobalt Oxide (NMC),
Lithium Cobalt Oxide (LCO),
Lithium Nickel Cobalt Aluminium Oxide (NCA),
a mixture of Lithium Cobalt Oxide and Lithium Nickel Cobalt

### Aluminium Oxide (Blend LCO-NCA).

In a variant, the cells 3 composing the device for storing energy 1 may be of the sodium-ion type. In any event, the various cells 3 and the levels 2 which comprise the cells 3 are intended to operate in a balanced manner. The imbalance of a level 2 may lead to performance losses, or even thermal runaway of this level and therefore to a malfunction of the device for storing energy 1.

The device for storing energy 1 also comprises an electronic control system 4, commonly referred to as a BMS (acronym for “Battery Management System”), that is configured to control the state and/or the operation of the device for storing energy 1. The electronic control system 4 may be configured to control each cell 3 individually or a set of cells 3 connected together in the form of a level 2. In particular, according to the embodiment presented, the electronic control system 4 is configured for determining and/or measuring in real time (i.e., instantaneously or almost instantaneously), the following data:
a mean voltage U_mea, equal to the mean of the voltages at the terminals of the different levels 2;
a minimum voltage U_min, equal to the voltage at the terminals of level 2 having the lowest voltage among all levels 2;
a maximum voltage U_max, equal to the voltage at the terminals of level 2 having the highest voltage among all levels 2;
a charging or discharging electric current I circulating through the device for storing energy 1.

Advantageously, a large majority of the batteries or energy storage units produced or in use throughout the world include an electronic control system 4 that is already configured to provide this data. To implement the invention, it is therefore not necessary to modify the existing electronic control systems 4.

It must be noted that because the different levels 2 are assembled in series, the electric current circulating through the device for storing energy 1 is equal to the electric current circulating through each of the levels 2. In addition, the electronic control system 4 may also be configured to provide other data including the voltage at the terminals of each level of the device for storing energy 1, the state of charge of the device for storing energy 1 (commonly referred to as SOC), the state of health of the device for storing energy 1 (commonly referred to as SOH), etc.

The electronic control system 4 is connected via a data exchange network to monitoring equipment 5, in accordance with one embodiment of the invention. The monitoring equipment 5 comprises, in particular a memory 6, a microprocessor 7, an input/output interface 8 configured to receive data from the electronic control system 4 and configured to communicate with a man-machine interface 9, for example, a computer equipped with a screen. The memory 6 is a data recording medium comprising instruction codes which, when executed by the microprocessor 7, lead the latter to implement a method for detecting a risk of malfunction through imbalance of the device for storing energy 1, in accordance with one embodiment of the invention.

The monitoring equipment 5 may be connected to the electronic control system 4 via a data exchange network, such as the Internet. In a variant, the monitoring equipment 5 may be integrated into a housing connected to the electronic control system 4 through a direct wired link, or even be integrated into the electronic control system 4.

A first embodiment of a method for detecting a risk of malfunction through imbalance of the device for storing energy 1 according to the invention will now be described. The method is based on data calculated or measured, through the electronic control system 4, during a charging or discharging phase of the energy storage unit 1. Advantageously, the method does not require full charging or discharging the device for storing energy 1. On the contrary, only one charge or one partial discharge is sufficient to implement the process. For example, the method may be implemented during a charge or discharge, in which the state of charge of the device for storing energy 1 varies between 25% and 75% of its total charging capacity. The determination method may consist of five steps E1, E2, E3, E4, E5, shown schematically in FIG. 2.

In a first step, E1, the electronic control system 4 transmits to the monitoring equipment 5, the values of the following quantities:

the voltage U_min of the level 2 having the lowest voltage,
the voltage U_max of the level 2 having the lowest voltage,
the mean voltage U_mea at the terminals of the different levels,
the electric current I circulating in the device for storing energy.

These values may, for example, be transmitted in the form of time series, periodically and/or at the end of each charging or discharging phase of the device for storing energy 1.

In a second step E2, a first function f1 is determined, referred to as the reference function, characterising a correct operation of at least one level 2. The term “correct operation” is understood to mean a normal or nominal operation of at least one level 2, i.e., the operation of a non-malfunctioning level. According to the first embodiment, the first function f1 is equal to a mean function f1 U_mea calculated on the basis of all of the levels of the device for storing energy 1. This first embodiment is therefore based on the hypothesis that the mean of all of the levels is representative of a correct operation. It may be agreed that this embodiment may be implemented only for a device for storing energy comprising a sufficient number of levels, so that the mean calculated throughout all of the levels reflects, according to the laws of statistics, a correct operation. Alternatively, and as will be seen later, other methods making it possible to determine a reference function may be proposed.

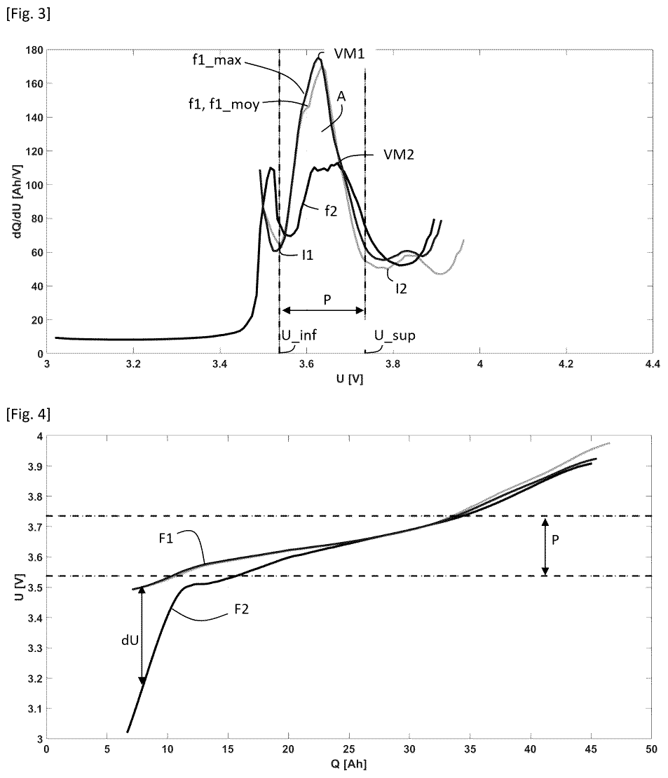

In general, the first function f1 is a mathematical function, representable on a graph, such as the graph in FIG. 3, and one that may be defined by a set of points. In particular, the first function defines a relationship between, on the one hand, an incremental capacitance of at least one level and, on the other hand, a voltage at the terminals of this at least one level. The incremental capacitance of a level is defined by a ratio of a charge quantity differential of that level over a voltage differential at the terminals of that level.

The mean function f1_U_mea may be determined as follows: to begin, a quantity of charges Q circulating in each level is determined by integrating the value of the electric current I over a charge or discharge period. A function establishing a relationship between the quantity of charges Q and a time elapsed is thus obtained. This function is combined with a function establishing a relationship between the mean voltage U_mea and the time elapsed. It is thus possible to construct an original function F1 (shown in FIG. 4) defining a relationship between the mean quantity of charges circulating in each level and the mean voltage U_mea. This original function may then be derived relative to the mean voltage U_mea to obtain the mean function f1U_mea. Thus, a mean incremental capacitance of the device for storing energy is obtained. The mean incremental capacitance is therefore a quantity relative to a quantity of charges circulating in each level. Defining the mean function f1_mea on the basis of a mean of all of the levels of the storage device makes it possible to make the detection method more robust, and in particular, to maintain effective detection even when one of the levels experiences an abnormally high voltage at its terminals.

In FIG. 3, the incremental capacitance is shown on the y-axis and is expressed in Ampere-hours per Volt. The voltage is shown on the x-axis and expressed in Volts. In FIG. 4, the quantity of charges circulating in a level is shown on the x-axis and expressed in Ampere-hours. The voltage at the terminals of a level is shown on the y-axis and expressed in Volts. According to the example shown, the voltage at the terminals of each level varies overall between 3.5V and 3.9V during a partial charge of this level. The quantity of charges accumulated by this level during this charge is approximately 30 Ah.

Alternatively, to determine the mean function f1_mea, it is possible to determine for each level, the function defining the relationship between the incremental capacitance of this level and the voltage at the terminals of this level. Then, it is possible to perform an arithmetic mean of the functions determined for each level. This method allows for more accurate detection, but requires more computational resources. Furthermore, this method requires the electronic control system 4 to provide the voltage at the terminals of each level of the device for storing energy.

According to a variant embodiment of the second step E2, at least one level whose operation is correct may be defined as the level 2 whose voltage at its terminals is closest to the mean voltage of all of the levels 2 of the device for storing energy 1.

According to other variant embodiments of the second step E2, the first function may be defined differently, for example, by means of a theoretical function or by identifying by any means one or more levels of the device for storing energy 1 which is functioning correctly and by determining the relationship between the incremental capacitance circulating in this or these levels and the voltage at the terminals of this or these levels.

According to another variant embodiment of the second step E2, the first function may take a form different from a function defining a relationship between the incremental capacitance and a voltage across the terminals of at least one level. In reference to FIG. 4, the first function may express a voltage at the terminals of at least one level as a function of a quantity of charges circulating in this at least one level. Thus, the first function may correspond to the original function F1 defined above.

Lastly, at the end of the second step E2, a first function is obtained, representative of a normal operation of any one or more levels. This first function may be determined according to several different methods but which have the common feature of defining a relationship between, on the one hand, a magnitude relative to a quantity of charges circulating in a level and, on the other hand, a voltage at the terminals of this level. This first function is therefore a reference function and serves as a basis for comparison to determine whether a particular level presents a risk of malfunction through imbalance.

In a third step E3, a second function f2 is determined, intended to be compared with the previously defined first function. The third step may be executed before or after the second step E2 or in parallel with the second step E2. According to the first embodiment, the second function f2 establishes a relationship between, on the one hand, the incremental capacitance of the level having the lowest voltage at its terminals among all of the stages of the device for storing energy and, on the other hand, the voltage U_min at the terminals of this level. The method for determining the second function f2 may be similar to the method for determining the first function. In particular, the second function f2 may be obtained by determining the quantity of charges circulating in the level with the lowest voltage at its terminals. It is thus possible to construct the original function F2 defining a relationship between this quantity of charges and the voltage U_min. This original function F2 may then be derived to obtain the function f2. As shown in FIG. 3, the second function f2 is intended to be compared with the mean function f1U_mea.

According to a variant embodiment, the detection method may also be implemented by comparing the previously defined original functions F1 and F2. In this event, the first function and the second function would be respectively equal to the original function F1 and equal to the original function F2. In general, the graph in which the second function is representable is identical to the graph in which the first function is representable. In other words, the form of the first function is the same as the form of the second function so as to allow a comparison of these two functions.

It must be noted that the quantity of charges circulating in each level is calculated more precisely during a charging or discharging phase of the device for storing energy according to a slow rate, in particular, a rate of less than or equal to C/5, that is to say, having a charge current making it possible to completely recharge the device for storing energy in at least five hours. Alternatively, the quantity of charges circulating in each level may also be calculated during a charging or discharging phase of the device for storing energy according to a faster rate, in particular, a rate strictly greater than C/5. In this case, steps E2 and E3 for determining the first function and/or the second function advantageously comprise a sub-step of filtering the magnitude relative to a quantity of charges circulating in a level.

The first function and the second function are defined over a given voltage range P. Because the first function is determined during a partial charge or discharge, said voltage range may be restricted compared to the voltage amplitude at the terminals of a level between a partially-charged state and a partially-discharged state. For example, with reference to FIG. 4, the voltage range P may be set substantially between about 3.55V and 3.75V, while the voltage at the terminals of a level may vary between 2.70V in the fully discharged state, and 4.2V in the fully charged state. The voltage amplitude of said voltage range may be, for example, less than or equal to 50% of the voltage amplitude between the minimum voltage and the maximum voltage at the terminals of a level 2.

When the first function expresses an incremental capacitance as a function of a voltage, it reaches a maximum value VM1, or in other words, an amplitude peak, for a given voltage. Advantageously, the voltage range P is defined so as to comprise the voltage for which the first function reaches the maximum value VM1. Furthermore, the first function may also comprise a first inflection point 11 and a second inflection point 12, either side of the maximum value VM1. The voltage range P may be defined such that it includes the voltages for which the first function reaches the first inflection point 11 and the second inflection point 12. In particular, the voltage range P may be defined in such a particular way that its lower limit U_lwr corresponds to the voltage value for which the first inflection point 11 is reached, and/or in such a way that its upper limit U_upr corresponds to the voltage value for which the second inflection point 12 is reached. As will be seen later, such a definition allows for a good compromise between, on the one hand, a relatively narrow voltage range, which makes it possible to implement the detection method during phases of charge or partial discharge. It must be noted that, in order to identify the first and second inflection points, the first function may optionally be filtered, in particular, smoothed, so as to eliminate any dubious variations.

Advantageously, the voltage range P may be defined dynamically. Indeed, it can be seen that the voltage for which the maximum value VM1 is reached may vary as a function of different parameters, in particular, as a function of the overall age status of the device for storing energy 1 and/or as a function of the temperature of the device for storing energy 1. Thus, a progressive offset or drift of the voltage for which the maximum value VM1 is reached may occur. The detection method may therefore optionally comprise a step E6 of defining the voltage range R. This step may comprise a first sub-step E61 of calculating an offset of the first function compared to a previous iteration of the detection method. This offset may be calculated, for example, by observing the offset of the voltage for which the maximum value VM1 of the first function is reached. Alternatively or additionally, this offset may be calculated as a function of an estimation of the state of health (SOH) of the device for storing energy 1 and/or as a function of its temperature. Then, in a second sub-step E62, it is possible to calculate a new lower limit and a new upper limit of the voltage range P, according to the previously calculated offset. In particular, each new limit may be calculated by applying, to the old limit, an offset corresponding to the offset of the voltage for which the maximum value VM1 is reached. The dynamic definition of the voltage range P makes it possible to maintain an efficient detection method over time and under a very wide variety of operating conditions.

Then, in a fourth step E4, a difference is calculated between said first function f1 and said second function f2. There are several ways for quantifying such a difference. According to a first embodiment, the difference between the first function and the second function may be equal to the difference between an integral of the first function over said voltage range P, and an integral of the second function over said voltage range P. In other words, the difference is then equal to the area A defined between the first function f1 and the second function f2 over the voltage range R. The integral of an incremental capacitance function of a level over the voltage range P may show a regional capacitance of this level. Advantageously, when the function defines a relationship between the incremental capacitance of a level and the voltage at the terminals of this level, and when the voltage range P is defined such that its lower and upper limits correspond to the two inflection points 11 and 12 as described previously, the voltage range thus defined makes it possible to improve the sensitivity of the detection. In fact, it is observed that it is essentially between the two inflection points 11 and 12 that the differences between the first function and the second function are the greatest.

Another advantage of determining said difference on the basis of an integral calculation is that this method may be implemented over any voltage range, including a voltage range in which the incremental capacitance curve does not reach its maximum value. Indeed, observing the first function f1 around its maximum value VM1 is not essential for implementing the detection method. Thus, the detection method makes it possible to detect an imbalance even when the device for storing energy undergoes incomplete charge and discharge cycles. Thus, alternatively, the lower limit U_lwr and the upper limit U_upr may also be determined so as to exclude the voltage for which the first function reaches the maximum value VM1. In other words, the lower limit U_lwr may be strictly greater than the voltage value for which the first function reaches the maximum value, or the upper limit U_upr may be strictly less than the voltage value for which the first function reaches the maximum value.

It must be noted that the detection method advantageously makes it possible to detect an imbalance that does not cause an offset in the voltage for which the maximum value of the incremental capacitance function is reached.

According to another embodiment, the difference between the first function and the second function may be calculated via an amplitude difference between these two functions. This amplitude difference may be equal to the largest amplitude deviation observed for a given voltage of the voltage range P. It is also possible to calculate the difference between the maximum value VM1 of the first function over said voltage range and a maximum value VM2 of the second function over said voltage range. According to this embodiment, it is sufficient simply to identify the maximum value of the first function and the second function over the voltage range R.

Alternatively, it is also possible to calculate the difference between the minimum value of the first function over said voltage range and the minimum value of the second function over said voltage range. Calculating an amplitude value difference between the first function f1 and the second function f2 is particularly simple to implement and economical in terms of calculations.

When the first function expresses a voltage at the terminals of at least one level as a function of a quantity of charges flowing in this at least one level, as shown in FIG. 4, said difference may be equal to the maximum amplitude difference between the first function F1 and the second function F2 over the voltage range P in question. In this case, this amplitude difference is a voltage difference. It can be seen from FIG. 4 that this difference (identified by dU) is particularly significant at low state of charge. This method therefore makes it possible to detect an imbalance during the first instances of recharging the device for storing energy, and in particular, well before the incremental capacity curves reach their maximum value.

In a fifth step E5, the difference calculated during the fourth step is compared with a threshold. Then, if the difference is strictly greater than said threshold, a signal may be saved in the memory 6 of the monitoring equipment 5. This signal may be read by the man-machine interface 9. Then, the man-machine interface 9 may generate an alert message indicating that a level of the device for storing energy presents a risk of malfunction through imbalance.

Advantageously, the comparison of functions defining a relationship between a magnitude relative to a quantity of charges circulating in the level and a voltage at the terminals of the level makes it possible to detect well in advance, a drift that indicates a risk of thermal runaway. Devices for storing energy 1 have thus been observed which on simple observation of the voltage at the terminals of the various levels have not made it possible to identify any anomaly several months before a malfunction has occurred. On the other hand, the implementation, according to the invention, of the method on this device for storing energy makes it possible to identify a risk of malfunction through imbalance several months before it occurs. In addition, the detection method generally makes it possible to identify the level of the device for storing energy responsible for this anomaly. The level in question may then easily be removed or replaced during any maintenance operation.

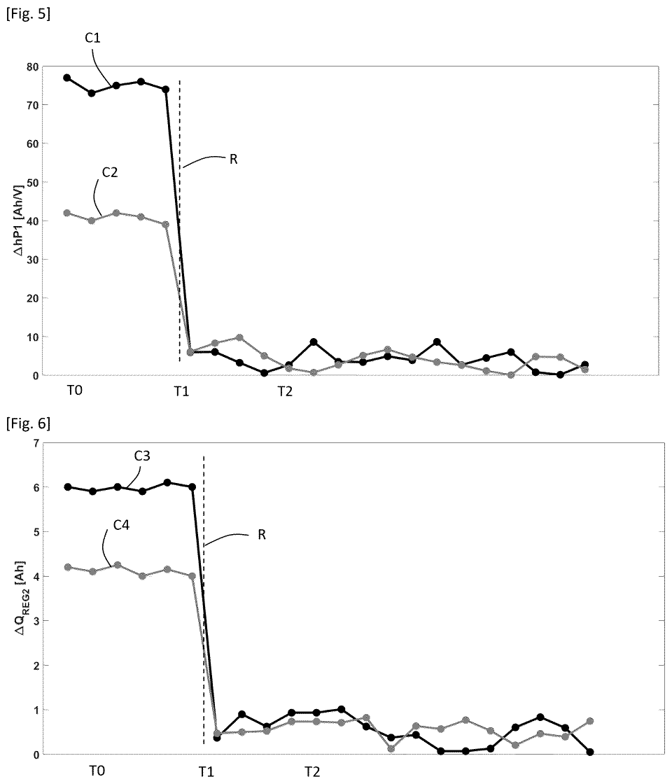

FIG. 5 is a graph comprising a first curve C1 illustrating the temporal evolution of the difference between the maximum value of the mean function f1_mea and the maximum value of the second function f2 over a time period of two years with a device for storing energy 1 comprising a level having a malfunction through imbalance (the reference T0 indicates the beginning of the period of two years, the reference T1 indicates a duration of one year from T0 and the reference T2 indicates a duration of two years from T0). For a little less than one year (that is to say, over the first six points of C1), the curve C1 reaches very significant values, which shows that there is a significant difference between the mean function f1_mea and the function f2. Then, during an intervention that has occurred after almost one year, and is represented by a dotted line R, the malfunctioning level has been replaced. It is thus observed that the curve C1 oscillates around a value close to zero, which means that the level having the lowest voltage at its terminals among the set of stages is operating close to the mean operation of the set of stages. The graph in FIG. 5 comprises a second curve C2 illustrating the temporal evolution in the difference between the maximum value of the mean function f1_mea and the maximum value of a function f_max over the same two-year time period with this same device for storing energy 1. The function f_max is defined as the function defining the relationship between, on the one hand, the incremental capacitance of the module whose voltage at its terminals is the highest among the set of modules 2 of the device for storing energy 1, and on the other hand, the voltage U_max. Curve C2 clearly has a much smaller amplitude than curve C1 up to the intervention date.

Similarly, FIG. 6 is a graph comprising a third curve C3 illustrating the temporal evolution of the difference between the integral of the mean function f1_mea over the range P and the integral of the function f2 over the range P, over a time period of two years with a device for storing energy 1 comprising a level having a malfunction through imbalance. As before, the curve C3 reaches very significant values, until the intervention date that has occurred after almost one year, during which the malfunctioning level has been replaced. Following this intervention, it is observed that the curve C3 oscillates around a value close to zero. The graph of FIG. 5 comprises a fourth curve C4 illustrating the temporal evolution of the difference between the integral of the mean function f1_mea over the range P and the integral of the function f_max over the range P, over a time period of two years, with this same device for storing energy 1. Curve C4 clearly has a much smaller amplitude than curve C3 up to the intervention date.

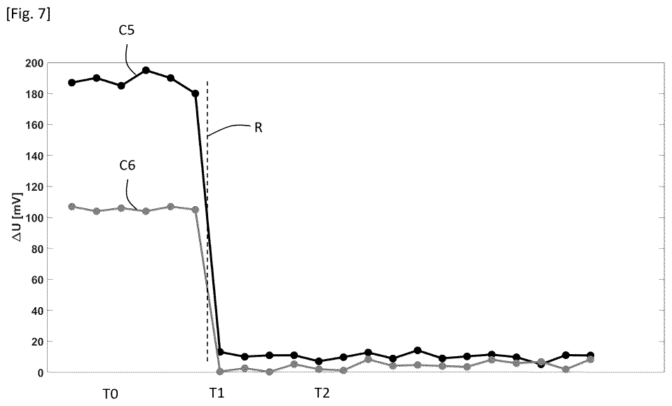

FIG. 7 is a graph comprising a fifth curve C5 illustrating the temporal evolution of the difference between the minimum value of the function F1 and the minimum value of the function F2 over a time period of two years with a device for storing energy 1 comprising a level having a malfunction through imbalance. In other words, the fifth curve C5 expresses the temporal evolution of the voltage difference dU, shown in FIG. 4. Until the date of intervention (represented by the line R), the curve C5 reaches significant values, in particular, between 100 mV and 300 mV. After the intervention, the curve C5 oscillates around a value close to zero. The graph of FIG. 7 also comprises a sixth curve C6 illustrating the temporal evolution of the difference between the minimum value of the function F1 and the minimum value of a function F_max over a time period of two years with the same device for storing energy 1. The function F_max is defined as the function defining a relationship between a quantity of charges circulating in the module, having the highest voltage at its terminals and the voltage U_max. Curve C9 clearly has a much smaller amplitude than curve C5 up to the intervention date.

Advantageously, the threshold, at which the difference is compared, is not zero. Indeed, due to different factors generating a certain dispersion in the operation of the stages, the difference calculated during the fourth step E4 may be non-zero although no level is malfunctioning. This difference is observed, in particular, on curves C2 and C4 presented above.

According to an improvement of the invention, the fifth step E5 may comprise:
a step E51 for comparing said difference with a first threshold and with a second threshold, the second threshold being strictly greater than the first threshold, and then
a step E52 for recording a first warning signal indicating a moderate risk, if said difference is greater than or equal to the first threshold and strictly less than the second threshold, and
a step E53 for recording a second warning signal indicating a high risk, if said difference is greater than or equal to the second threshold.
The warning signal and the second signal are intended to be saved in the memory 6 of the monitoring equipment 5. These signals may then be consulted by the man-machine interface 9 in order to produce an alert message adapted to the situation.

Advantageously, the first threshold is determined as a function of a normal dispersion of said magnitude relative to a quantity of charges circulating in a level. For example, this first threshold may be determined experimentally by observing correctly functioning levels in a device for storing energy. The first threshold may thus be defined as equal to or slightly greater than the largest difference (as calculated in step E4) observed over a sufficiently long period, with a device for storing energy in which all of the levels operate correctly.

The second threshold may be determined as a function of a permissible overcharge by the electrochemical cells used. The permissible overcharge denotes the percentage of charges which a cell is capable of supporting before irreversible degradation, a magnitude then transcribed, if necessary, to the quantity of charge permissible for a level. Indeed, it is found that the difference between the integral of the mean function f1_mea or f_max and the integral of the second function substantially corresponds to a quantity of excessive charges for the level. In other words, if this difference exceeds the permissible overcharge, then thermal runaway will definitely occur. The second threshold may therefore advantageously be defined as a fraction of the permissible overcharge, for example 50% of the permissible overcharge. Lastly, thanks to the invention, there is a method for detection of a risk of malfunction through imbalance of a level of a device for storing energy that may be implemented during partial charges and/or discharges. Compared to known methods, this method makes it possible to detect an imbalance at an early stage, that allows better maintenance of the device for storing energy. In particular, the method makes it possible to detect imbalances which were previously difficult to detect, in particular, imbalances caused by a state of charge (SOC) deviation on chemistries which do not have a significant relationship between voltage and state of charge (SOC), such as an LFP Li-ion chemistry, or caused by a state of health (SOH) deviation of the various levels of the device for storing energy.

The invention has the advantage of not requiring any prior characterisation of the device for storing energy or a similar device for storing energy. Indeed, according to the invention, said function characterising a correct operation of at least one level is established directly with the device for storing energy for which it is sought to detect a risk of malfunction through imbalance. According to the invention, the operation of the level having the lowest voltage at its terminals is compared with the operation of other levels of the same device for storing energy. The method according to the invention is therefore much simpler to implement than the detection methods previously known. The method may be implemented on any device for storing energy comprising a set of levels electrically connected to one another in series, without characterisation or calculation of a good theoretical operation of this device for storing energy. The monitoring equipment implementing the detection method according to the invention is thus “plug-and-play”, i.e., it is functional as soon as it is connected to the electronic control system of a device for storing energy.

1. A method for detecting a risk of malfunction through imbalance of a device for storing energy (1) comprising a set of levels (2) electrically connected to one another in series and consisting of electrochemical cells electrically connected to one another in parallel, characterised in that it comprises:
a step (E2) for determining a first function (f1) characterising a correct operation of at least one level, the first function defining a relationship between, on the one hand, a magnitude relative to a quantity of charges circulating in at least one level and, on the other hand, a voltage at the terminals of at least one level, the first function being defined over a given voltage range (P),
a step (E3) of determining a second function (f2) characterising the operation of a level having the lowest voltage at its terminals among all of the levels of the device for storing energy (1), the second function defining a relationship between, on the one hand, said magnitude relative to a quantity of charges circulating in the level having the lowest voltage at its terminals among all of the levels of the device for storing energy and, on the other hand, a voltage at the terminals of this level, the second function being defined over said voltage range, then
a step (E4) for calculating an amplitude value difference or an integral value difference between said first function and said second function, and then
a step (E5) of comparing said difference with a threshold.

2. The detection method according to claim 1, characterised in that the first function (f1) defines a relationship between, on the one hand, a mean over all of the levels of the device for storing energy of said magnitude relative to a quantity of charges circulating in each level and, on the other hand, a mean voltage at the terminals of each level of the device for storing energy.

3. The detection method according to claim 1, characterised in that said magnitude relative to a quantity of charges circulating in a level is an incremental capacitance of this level.

4. The detection method according to claim 1, characterised in that said voltage range (P) comprises a lower limit (U_lwr) and an upper limit (U_upr), the lower limit corresponding to a first inflection point (11) of the first function and/or the upper limit corresponding to a second inflection point (12) of the first function, the first inflection point and the second inflection point being positioned on either side of a maximum value (VM1) reached by the first function.

5. The detection method according to claim 3, characterised in that the first function reaches a maximum value (VM1) for a given voltage value (U_VM1), and in that said voltage range (P) comprises a lower limit (U_lwr) and an upper limit (U_upr), the lower limit (U_lwr) being strictly greater than the voltage value for which the first function reaches the maximum value or the upper limit (U_upr) being strictly less than the voltage value for which the first function reaches the maximum value.

6. The detection method according to claim 1, characterised in that it comprises a step (E6) for defining said voltage range (P) comprising:
sub-step (E61) of calculating an offset of the first function (f1) compared to a previous iteration of the detection method, and then,
a sub-step (E62) of calculating a lower limit (U_lwr) and an upper limit (U_upr) of the voltage range according to the previously calculated offset.

7. The detection method according to claim 1, characterised in that said first function (f1) and/or said second function (f2) are determined:
either during a charging or discharging phase of the device for storing energy according to a slow rate, in particular, a rate of less than or equal to C/5,
or during a phase for charging or discharging the device for storing energy according to a fast rate, in particular, a rate strictly greater than C/5, the step (E2, E3) of determining the first function and/or the second function then comprising a sub-step of filtering the magnitude relative to a quantity of charges circulating in a level.

8. The method of detection according to claim 1, characterised in that the said difference is equal to:
the difference (A) between an integral of the first function (f1) over said voltage range (P), and an integral of the second function (f2) over said voltage range, or
the difference between a maximum value (VM1) of the first function (f1) over said voltage range and a maximum value of the second function (f2) over said voltage range.

9. The detection method according to claim 1, characterised in that said first function (f1) and/or said second function (f2) are determined during a charge or a partial discharge of the device for storing energy (1), said voltage range (P) comprising a lower limit (U_lwr) corresponding to a state of charge of the device for storing energy of greater than or equal to 25% and/or in that said voltage range comprising an upper limit (U_upr) corresponding to a state of charge of the device for storing energy of less than or equal to 75%.

10. The detection method according to claim 1, characterised in that the step (E5) for comparing said difference with a threshold comprises:
a sub-step (E51) of comparing said difference with a first threshold and with a second threshold, the second threshold being strictly greater than the first threshold, and then
a sub-step (E52) of recording a first warning signal indicating a moderate risk, if said difference is greater than or equal to the first threshold and strictly less than the second threshold, and
a sub-step (E53) of recording a second warning signal indicating a high risk, if said difference is greater than or equal to the second threshold.

11. The detection method according to claim 1, characterised in that the first threshold is determined as a function of an observed dispersion of said magnitude relative to a quantity of charges circulating in a level, and in that the second threshold is determined as a function of an overcharge permissible by the level before thermal runaway.

12. The monitoring equipment (5) of a device for storing energy (1) comprising a set of electrochemical levels (2) electrically connected in series, characterised in that it comprises hardware (6, 7, 8) and software means configured to implement the method for detecting a risk of malfunction through imbalance of the device for storing energy according to claim 1.
